(19) United States
(12) Patent Application Publication
(10) Pub. No.: US 2016/0232858 A1
(43) Pub. Date: Aug. 11, 2016

(54) CREEP RESISTANT REFLECTIVE STRUCTURE IN MEMS DISPLAY

(71) Applicant: QUALCOMM MEMS Technologies, Inc., San Diego, CA (US)

(72) Inventors: Yaoling Pan, San Diego, CA (US); Victor Louis Arockiaraj Pushparaj, Milpitas, CA (US); John Hong, San Clemente, CA (US); Edward Chan, San Diego, CA (US)

(21) Appl. No.: 14/619,991

(22) Filed: Feb. 11, 2015

(51) Int. Cl. G09G 3/34; C23C 14/00; G02B 26/02

(52) U.S. Cl. CPC G09G 3/3466; G02B 26/02; C23C 14/0042

(57) ABSTRACT

This disclosure provides devices, systems, and methods for improving creep resistance and mechanical strength of a MEMS display device. The MEMS display device can include a movable reflective structure connected and supported by a support structure. The movable reflective structure can include at least a transition metal layer sandwiched between two aluminum or aluminum alloy layers. The aluminum or aluminum alloy layers can be doped with the transition metal upon annealing. The transition metal layer between the aluminum or aluminum alloy layers can control the mechanical, optical, and electrical properties of the MEMS display device.

### TECHNICAL FIELD

This disclosure relates to microelectromechanical systems (MEMS) display devices and more particularly to annealed multilayer thin film stacks in movable reflective structures to improve creep resistance in MEMS display devices.

### DESCRIPTION OF THE RELATED TECHNOLOGY

Electromechanical systems (EMS) include devices having electrical and mechanical elements, actuators, transducers, sensors, optical components such as mirrors and optical films, and electronics. EMS devices or elements can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of EMS device is called an interferometric modulator (IMOD). The term IMOD or interferometric light modulator refers to a device that selectively absorbs and/or reflects light using the principles of optical interference. In some implementations, an IMOD display element may include a pair of conductive plates, one or both of which may be transparent and/or reflective, wholly or in part, and capable of relative motion upon application of an appropriate electrical signal. For example, one plate may include a stationary layer deposited over, on or supported by a substrate and the other plate may include a reflective membrane separated from the stationary layer by an air gap. The position of one plate in relation to another can change the optical interference of light incident on the IMOD display element. IMOD-based display devices have a wide range of applications, and are anticipated to be used in improving existing products and creating new products, especially those with display capabilities.

### SUMMARY

The systems, methods and devices of this disclosure each have several innovative aspects, no single one of which is solely responsible for the desirable attributes disclosed herein.

One innovative aspect of the subject matter described in this disclosure can be implemented in a MEMS display device including a substrate, a movable reflective structure over the substrate, where the movable reflective structure includes an annealed thin film stack, and one or more support structures over the substrate and connected to the movable reflective structure to support the movable reflective structure. The annealed thin film stack includes a first layer including an aluminum or aluminum alloy, a second layer including aluminum or aluminum alloy and over the first layer, and a third layer between the first layer and the second layer. The third layer is in contact with at least one of the first layer and the second layer, where the third layer includes a transition metal, the transition metal including at least one of: zirconium, scandium, ruthenium, titanium, tantalum, molybdenum, and chromium.

In some implementations, one or both of the first layer and the second layer is doped with about 0.1 atomic % to about 10 atomic % of the transition metal. In some implementations, a stress of the movable reflective structure is less than about 200 MPa. In some implementations, the third layer has a thickness of less than about 5 nm, and the first layer and the second layer each have a thickness of equal to or greater than about 20 nm. In some implementations, a reflectance of the movable reflective structure is greater than about 80%. In some implementations, each of the first layer and the second layer is doped to include between about 1 atomic % and about 20 atomic % of one or both of oxygen and nitrogen. In some implementations, the first layer and the second layer are substantially identical in composition and thickness.

Another innovative aspect of the subject matter described in this disclosure can be implemented in a method of manufacturing a MEMS display device. The method includes providing a substrate, forming a support structure over the substrate, forming a movable reflective structure over the substrate and connected to the support structure, and annealing the movable reflective structure. The movable reflective structure includes a first layer including aluminum or aluminum alloy, a second layer including aluminum or aluminum alloy and over the first layer, and a third layer between the first layer and the second layer. The third layer is in contact with at least one of the first layer and the second layer, where the third layer includes a transition metal, the transition metal including at least one of: zirconium, scandium, ruthenium, titanium, tantalum, molybdenum, and chromium.

In some implementations, forming the movable reflective structure includes depositing the first layer over the substrate, depositing the third layer on the first layer, and depositing the second layer on the third layer. In some implementations, depositing the first layer includes doping the first layer with one or both of oxygen and nitrogen, and depositing the second layer includes doping the second layer with one or both of oxygen and nitrogen. In some implementations, the method further includes depositing a fourth layer between the substrate and the first layer, where the fourth layer is substantially identical in thickness and composition with the third layer. In some implementations, the method further includes depositing a fifth layer between the substrate and the fourth layer, where the fifth layer is substantially identical in thickness and composition with the first layer and the second layer.

Details of one or more implementations of the subject matter described in this disclosure are set forth in the accompanying drawings and the description below. Although the examples provided in this disclosure are primarily described in terms of EMS and MEMS-based displays the concepts provided herein may apply to other types of displays such as liquid crystal displays (LCDs), organic light-emitting diode (“OLED”) displays, and field emission displays. Other features, aspects, and advantages will become apparent from the description, the drawings and the claims. Note that the relative dimensions of the following figures may not be drawn to scale.

### BRIEF DESCRIPTION OF THE DRAWINGS

FIG. 1 is an isometric view illustration depicting two adjacent interferometric modulator (IMOD) display elements in a series or array of display elements of an IMOD display device.

FIG. 2 is a system block diagram illustrating an electronic device incorporating an IMOD-based display including a three element by three element array of IMOD display elements.

FIGS. 3A-3E are cross-sectional illustrations of varying implementations of IMOD display elements.

FIG. 4 is a flow diagram illustrating a manufacturing process for an IMOD display or display element.

FIGS. 5A-5E are cross-sectional illustrations of various stages in a process of making an IMOD display or display element.

FIG. 6 shows a perspective view of an example MEMS display device having a movable reflective structure spaced apart from a stationary electrode by a gap.

FIG. 7A shows a cross-sectional side view of an example thin film stack for a movable reflective structure with a transition metal layer sandwiched between two reflective layers.

FIG. 7B shows a cross-sectional side view of an example movable reflective structure including a thin film stack over an optical layer.

FIG. 7C shows a cross-sectional side view of an example thin film stack for a movable reflective structure with an additional transition metal layer.

FIG. 7D shows a cross-sectional side view of an example thin film stack for a movable reflective structure with an additional transition metal layer and an additional reflective layer.

FIG. 8A shows a graph illustrating stress of a movable reflective structure as a function of the zirconium deposition times, where the movable reflective structure includes an aluminum alloy layer sandwiched between two zirconium layers.

FIG. 8B shows a graph illustrating reflectance of the movable reflective structure from FIG. 8A as a function of the zirconium deposition times.

FIG. 8C shows a graph illustrating stress of a movable reflective structure as a function of zirconium deposition times, where the movable reflective structure includes zirconium sandwiched between two aluminum alloy layers.

FIG. 8D shows a graph illustrating reflectance of the movable reflective structure from FIG. 8C as a function of the zirconium deposition times.

FIG. 8E shows a graph illustrating stress of a movable reflective layer as a function of the zirconium deposition times, where the movable reflective structure includes zirconium sandwiched between two aluminum alloy layers.

FIG. 8F shows a graph illustrating reflectance of the movable reflective structure from FIG. 8E as a function of zirconium deposition times.

FIG. 8G shows a graph illustrating stress of a movable reflective structure as a function of zirconium deposition times, where the movable reflective structure includes zirconium sandwiched between two thick aluminum alloy layers.

FIG. 8H shows a graph illustrating reflectance of the movable reflective structure from FIG. 8G as a function of zirconium deposition times.

FIG. 8I shows a graph illustrating stress of a movable reflective structure as a function of zirconium deposition times, where the movable reflective structure includes zirconium sandwiched between two thick aluminum alloy layers.

FIG. 8J shows a graph illustrating reflectance of the movable reflective structure from FIG. 8I as a function of zirconium deposition times.

FIG. 9 is a flow diagram of an example method of manufacturing a MEMS display device.

FIGS. 10A and 10B are system block diagrams illustrating a display device that includes a plurality of IMOD display elements.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device, apparatus, or system that can be configured to display an image, whether in motion (such as video) or stationary (such as still images), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, global positioning system (GPS) receivers/navigators, cameras, digital media players (such as MP3 players), camcorders, game consoles, wrist watches, clocks, calculators, television monitors, flat panel displays, electronic reading devices (e.g., e-readers), computer monitors, auto displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS) applications including microelectromechanical systems (MEMS) applications, as well as non-EMS applications), aesthetic structures (such as display of images on a piece of jewelry or clothing) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

Some implementations described herein relate to a MEMS display device having improved creep resistance and stress control. The MEMS display device can include a substrate, a movable reflective structure (e.g., mirror) over the substrate, and one or more support structures over the substrate and connected to the movable reflective structure to support the movable reflective structure. The movable reflective structure can include a multilayer thin film stack, where the multilayer thin film stack can include at least a thin transition metal layer sandwiched between two aluminum or aluminum alloy layers. The multilayer thin film stack can be annealed to permit the aluminum or aluminum alloy layers to be doped with the transition metal. The microstructures of the multilayer thin film stack can be altered or controlled through the annealing processes to control the stress in the movable reflective structure, improve the creep resistance of the MEMS display device, and minimize compromising the reflectance and electrical conductivity of the MEMS display device. In some implementations, the aluminum or aluminum alloy layers can be doped with oxygen and/or nitrogen to further enhance mechanical properties.

Particular implementations of the subject matter described in this disclosure can be implemented to realize one or more of the following potential advantages. The annealed multilayer thin film stack with a transition metal layer sandwiched between two aluminum or aluminum alloy layers provides greater resistance against creep. Accordingly, the MEMS display device can be more resistant to thermal cycles and mechanical stresses so that the lifetime of the MEMS display device can be increased. The annealed multilayer thin film stack can also increase the mechanical strength of the MEMS display device by reducing the stress in the movable reflective structure. The annealed multilayer thin film stack can also improve the optical characteristics of the MEMS display device by increasing the reflectance of the movable reflective structure. Furthermore, the incorporation of a transition metal layer between two aluminum or aluminum alloy layers can provide greater control over the mechanical, optical, and electrical properties of the movable reflective structure. In some implementations, such properties may be tuned by the thickness of the transition metal layer and/or the annealing conditions of the multilayer thin film stack.

An example of a suitable MEMS display device or apparatus, to which the described implementations may apply, is a reflective display device. Reflective display devices can incorporate interferometric modulator (IMOD) display elements that can be implemented to selectively absorb and/or reflect light incident thereon using principles of optical interference. IMOD display elements can include a partial optical absorber, a reflector that is movable with respect to the absorber, and an optical resonant cavity defined between the absorber and the reflector. In some implementations, the reflector can be moved to two or more different positions, which can change the size of the optical resonant cavity and thereby affect the reflectance of the IMOD. The reflectance spectra of IMOD display elements can create fairly broad spectral bands that can be shifted across the visible wavelengths to generate different colors. The position of the spectral band can be adjusted by changing the thickness of the optical resonant cavity. One way of changing the optical resonant cavity is by changing the position of the reflector with respect to the absorber.

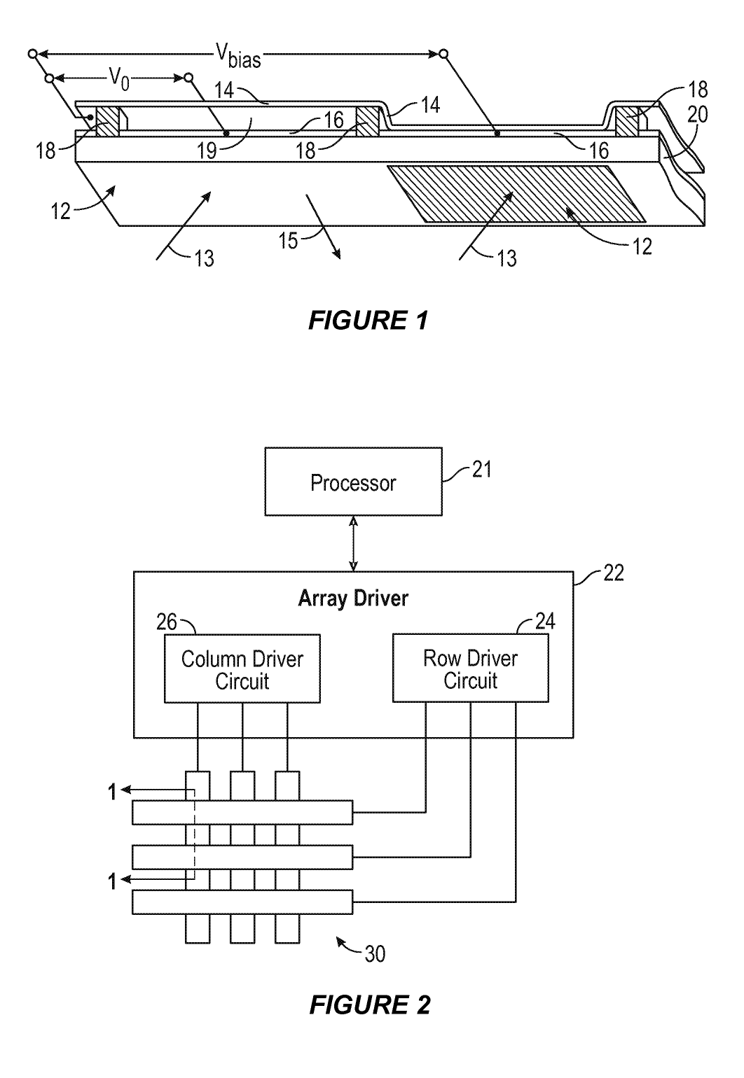

FIG. 1 is an isometric view illustration depicting two adjacent interferometric modulator (IMOD) display elements in a series or array of display elements of an IMOD display device. The IMOD display device includes one or more interferometric EMS, such as MEMS, display elements. In these devices, the interferometric MEMS display elements can be configured in either a bright or dark state. In the bright (“relaxed,” “open” or “on,” etc.) state, the display element reflects a large portion of incident visible light. Conversely, in the dark (“actuated,” “closed” or “off,” etc.) state, the display element reflects little incident visible light. MEMS display elements can be configured to reflect predominantly at particular wavelengths of light allowing for a color display in addition to black and white. In some implementations, by using multiple display elements, different intensities of color primaries and shades of gray can be achieved.

The IMOD display device can include an array of IMOD display elements which may be arranged in rows and columns. Each display element in the array can include at least a pair of reflective and semi-reflective layers, such as a movable reflective layer (i.e., a movable layer, also referred to as a mechanical layer) and a fixed partially reflective layer (i.e., a stationary layer), positioned at a variable and controllable distance from each other to form an air gap (also referred to as an optical gap, cavity or optical resonant cavity). The movable reflective layer may be moved between at least two positions. For example, in a first position, i.e., a relaxed position, the movable reflective layer can be positioned at a distance from the fixed partially reflective layer. In a second position, i.e., an actuated position, the movable reflective layer can be positioned more closely to the partially reflective layer. Incident light that reflects from the two layers can interfere constructively and/or destructively depending on the position of the movable reflective layer and the wavelength(s) of the incident light, producing either an overall reflective or non-reflective state for each display element. In some implementations, the display element may be in a reflective state when unactuated, reflecting light within the visible spectrum, and may be in a dark state when actuated, absorbing and/or destructively interfering light within the visible range. In some other implementations, however, an IMOD display element may be in a dark state when unactuated, and in a reflective state when actuated. In some implementations, the introduction of an applied voltage can drive the display elements to change states. In some other implementations, an applied charge can drive the display elements to change states.

The depicted portion of the array in FIG. 1 includes two adjacent interferometric MEMS display elements in the form of IMOD display elements 12. In the display element 12 on the right (as illustrated), the movable reflective layer 14 is illustrated in an actuated position near, adjacent or touching the optical stack 16. The voltage V_{bias} applied across the display element 12 on the right is sufficient to move and also maintain the movable reflective layer 14 in the actuated position. In the display element 12 on the left (as illustrated), a movable reflective layer 14 is illustrated in a relaxed position at a distance (which may be predetermined based on design parameters) from an optical stack 16, which includes a partially reflective layer. The voltage V₀ applied across the display element 12 on the left is insufficient to cause actuation of the movable reflective layer 14 to an actuated position such as that of the display element 12 on the right.

In FIG. 1, the reflective properties of IMOD display elements 12 are generally illustrated with arrows indicating light 13 incident upon the IMOD display elements 12, and light 15 reflecting from the display element 12 on the left. Most of the light 13 incident upon the display elements 12 may be transmitted through the transparent substrate 20, toward the optical stack 16. A portion of the light incident upon the optical stack 16 may be transmitted through the partially reflective layer of the optical stack 16, and a portion will be reflected back through the transparent substrate 20. The portion of light 13 that is transmitted through the optical stack 16 may be reflected from the movable reflective layer 14, back toward (and through) the transparent substrate 20. Interference (constructive and/or destructive) between the light reflected from the partially reflective layer of the optical stack 16 and the light reflected from the movable reflective layer 14 will determine in part the intensity of wavelength(s) of light 15 reflected from the display element 12 on the viewing or substrate side of the device. In some implementations, the transparent substrate 20 can be a glass substrate (sometimes referred to as a glass plate or panel). The glass substrate may be or include, for example, a borosilicate glass, a soda lime glass, quartz, Pyrex, or other suitable glass material. In some implementations, the glass substrate may have a thickness of 0.3, 0.5 or 0.7 millimeters, although in some implementations the glass substrate can be thicker (such as tens of millimeters) or thinner (such as less than 0.3 millimeters). In some implementations, a non-glass substrate can be used, such as a polycarbonate, acrylic, polyethylene terephthalate (PET) or polyether ether ketone (PEEK) substrate. In such an implementation, the non-glass substrate will likely have a thickness of less than 0.7 millimeters, although the substrate may be thicker depending on the design considerations. In some implementations, a non-transparent substrate, such as a metal foil or stainless steel-based substrate can be used. For example, a reverse-IMOD-based display, which includes a fixed reflective layer and a movable layer which is partially transmissive and partially reflective, may be configured to be viewed from the opposite side of a substrate as the display elements 12 of FIG. 1 and may be supported by a non-transparent substrate.

The optical stack 16 can include a single layer or several layers. The layer(s) can include one or more of an electrode layer, a partially reflective and partially transmissive layer, and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals (e.g., chromium and/or molybdenum), semiconductors, and dielectrics. The partially reflective layer can be formed of one or more layers of materials, and each of the layers can be formed of a single material or a combination of materials. In some implementations, certain portions of the optical stack 16 can include a single semi-transparent thickness of metal or semiconductor which serves as both a partial optical absorber and electrical conductor, while different, electrically more conductive layers or portions (e.g., of the optical stack 16 or of other structures of the display element) can serve to bus signals between IMOD display elements. The optical stack 16 also can include one or more insulating or dielectric layers covering one or more conductive layers or an electrically conductive/partially absorptive layer.

In some implementations, at least some of the layer(s) of the optical stack 16 can be patterned into parallel strips, and may form row electrodes in a display device as described further below. As will be understood by one having ordinary skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of supports, such as the illustrated posts 18, and an intervening sacrificial material located between the posts 18. When the sacrificial material is etched away, a defined gap 19, or optical cavity, can be formed between the movable reflective layer 14 and the optical stack 16. In some implementations, the spacing between posts 18 may be approximately 1-1000 μm, while the gap 19 may be approximately less than 10,000 Angstroms (Å).

In some implementations, each IMOD display element, whether in the actuated or relaxed state, can be considered as a capacitor formed by the fixed and moving reflective layers. When no voltage is applied, the movable reflective layer 14 remains in a mechanically relaxed state, as illustrated by the display element 12 on the left in FIG. 1, with the gap 19 between the movable reflective layer 14 and optical stack 16. However, when a potential difference, i.e., a voltage, is applied to at least one of a selected row and column, the capacitor formed at the intersection of the row and column electrodes at the corresponding display element becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated display element 12 on the right in FIG. 1. The behavior can be the same regardless of the polarity of the applied potential difference. Though a series of display elements in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. In some implementations, the rows may be referred to as “common” lines and the columns may be referred to as “segment” lines, or vice versa. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

FIG. 2 is a system block diagram illustrating an electronic device incorporating an IMOD-based display including a three element by three element array of IMOD display elements. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22. The array driver 22 can include a row driver circuit 24 and a column driver circuit 26 that provide signals to, for example a display array or panel 30. The cross section of the IMOD display device illustrated in FIG. 1 is shown by the lines 1-1 in FIG. 2. Although FIG. 2 illustrates a 3×3 array of IMOD display elements for the sake of clarity, the display array 30 may contain a very large number of IMOD display elements, and may have a different number of IMOD display elements in rows than in columns, and vice versa.

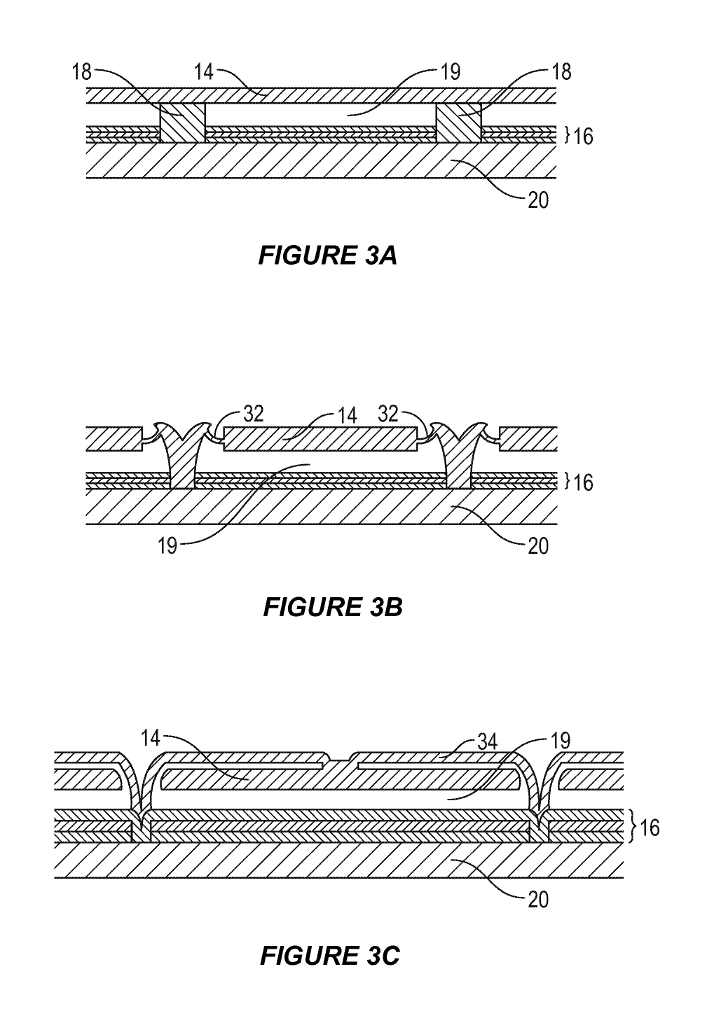

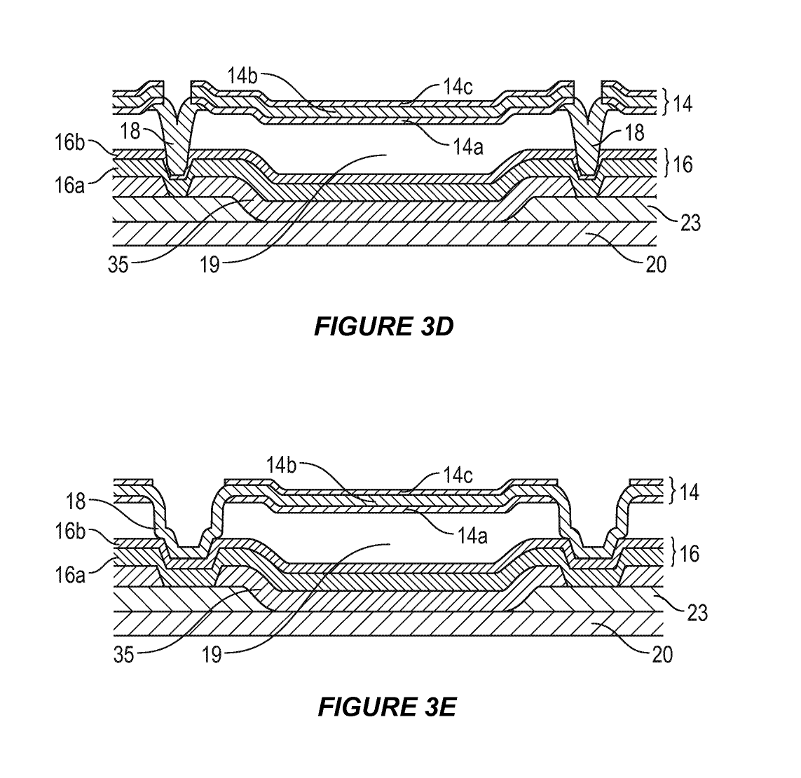

The details of the structure of IMOD displays and display elements may vary widely. FIGS. 3A-3E are cross-sectional illustrations of varying implementations of IMOD display elements. FIG. 3A is a cross-sectional illustration of an IMOD display element, where a strip of metal material is deposited on supports 18 extending generally orthogonally from the substrate 20 forming the movable reflective layer 14. In FIG. 3B, the movable reflective layer 14 of each IMOD display element is generally square or rectangular in shape and attached to supports at or near the corners, on tethers 32. In FIG. 3C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as implementations of “integrated” supports or support posts 18. The implementation shown in FIG. 3C has additional benefits deriving from the decoupling of the optical functions of the movable reflective layer 14 from its mechanical functions, the latter of which are carried out by the deformable layer 34. This decoupling allows the structural design and materials used for the movable reflective layer 14 and those used for the deformable layer 34 to be optimized independently of one another.

FIG. 3D is another cross-sectional illustration of an IMOD display element, where the movable reflective layer 14 includes a reflective sub-layer 14a. The movable reflective layer 14 rests on a support structure, such as support posts 18. The support posts 18 provide separation of the movable reflective layer 14 from the lower stationary electrode, which can be part of the optical stack 16 in the illustrated IMOD display element. For example, a gap 19 is formed between the movable reflective layer 14 and the optical stack 16, when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO₂). In some implementations, the support layer 14b can be a stack of layers, such as, for example, a SiO₂/SiON/SiO₂ tri-layer stack. Either or both of the reflective sub-layer 14a and the conductive layer 14c can include, for example, an aluminum (Al) alloy with about 0.5% copper (Cu), or another reflective metallic material. Employing conductive layers 14a and 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 3D, some implementations also can include a black mask structure 23, or dark film layers. The black mask structure 23 can be formed in optically inactive regions (such as between display elements or under the support posts 18) to absorb ambient or stray light. The black mask structure 23 also can improve the optical properties of a display device by inhibiting light from being reflected from or transmitted through inactive portions of the display, thereby increasing the contrast ratio. Additionally, at least some portions of the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. In some implementations, the black mask structure 23 can be an etalon or interferometric stack structure. For example, in some implementations, the interferometric stack black mask structure 23 includes a molybdenum-chromium (MoCr) layer that serves as an optical absorber, an SiO₂ layer, and an aluminum alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, tetrafluoromethane (or carbon tetrafluoride, CFO and/or oxygen (O₂) for the MoCr and SiO₂ layers and chlorine (Cl₂) and/or boron trichloride (BCl₃) for the aluminum alloy layer. In such interferometric stack black mask structures 23, the conductive absorbers can be used to transmit or bus signals between lower, stationary electrodes in the optical stack 16 of each row or column. In some implementations, a spacer layer 35 can serve to generally electrically isolate electrodes (or conductors) in the optical stack 16 (such as the absorber layer 16a) from the conductive layers in the black mask structure 23.

FIG. 3E is another cross-sectional illustration of an IMOD display element, where the movable reflective layer 14 is self-supporting. While FIG. 3D illustrates support posts 18 that are structurally and/or materially distinct from the movable reflective layer 14, the implementation of FIG. 3E includes support posts that are integrated with the movable reflective layer 14. In such an implementation, the movable reflective layer 14 contacts the underlying optical stack 16 at multiple locations, and the curvature of the movable reflective layer 14 provides sufficient support that the movable reflective layer 14 returns to the unactuated position of FIG. 3E when the voltage across the IMOD display element is insufficient to cause actuation. In this way, the portion of the movable reflective layer 14 that curves or bends down to contact the substrate or optical stack 16 may be considered an “integrated” support post. One implementation of the optical stack 16, which may contain a plurality of several different layers, is shown here for clarity including an optical absorber 16a, and a dielectric 16b. In some implementations, the optical absorber 16a may serve both as a stationary electrode and as a partially reflective layer. In some implementations, the optical absorber 16a can be an order of magnitude thinner than the movable reflective layer 14. In some implementations, the optical absorber 16a is thinner than the reflective sub-layer 14a.

In implementations such as those shown in FIGS. 3A-3E, the IMOD display elements form a part of a direct-view device, in which images can be viewed from the front side of the transparent substrate 20, which in this example is the side opposite to that upon which the IMOD display elements are formed. In these implementations, the back portions of the device (that is, any portion of the display device behind the movable reflective layer 14, including, for example, the deformable layer 34 illustrated in FIG. 3C) can be configured and operated upon without impacting or negatively affecting the image quality of the display device, because the reflective layer 14 optically shields those portions of the device. For example, in some implementations a bus structure (not illustrated) can be included behind the movable reflective layer 14 that provides the ability to separate the optical properties of the modulator from the electromechanical properties of the modulator, such as voltage addressing and the movements that result from such addressing.

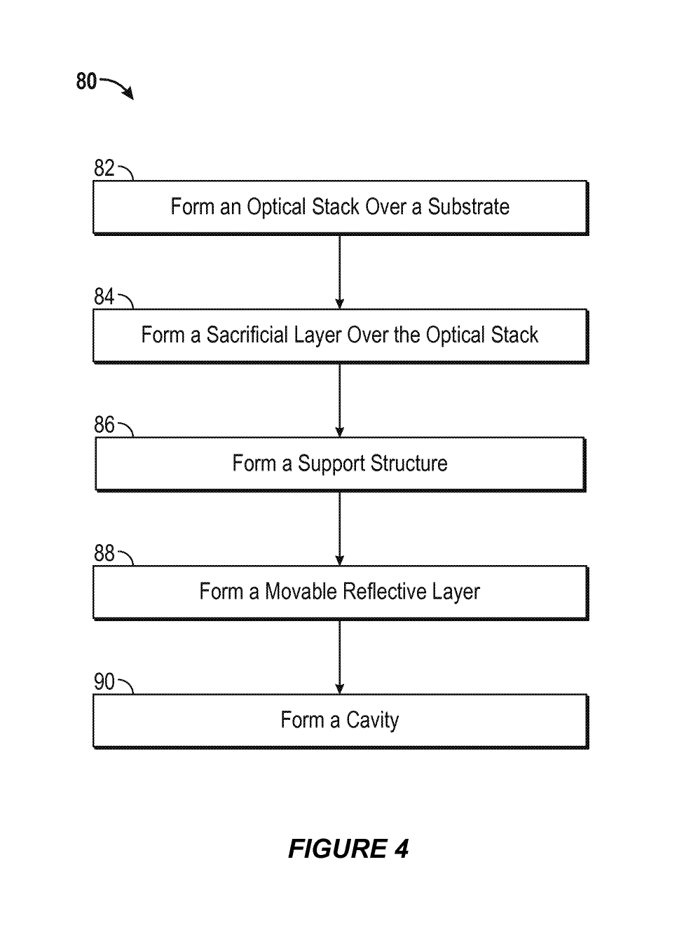

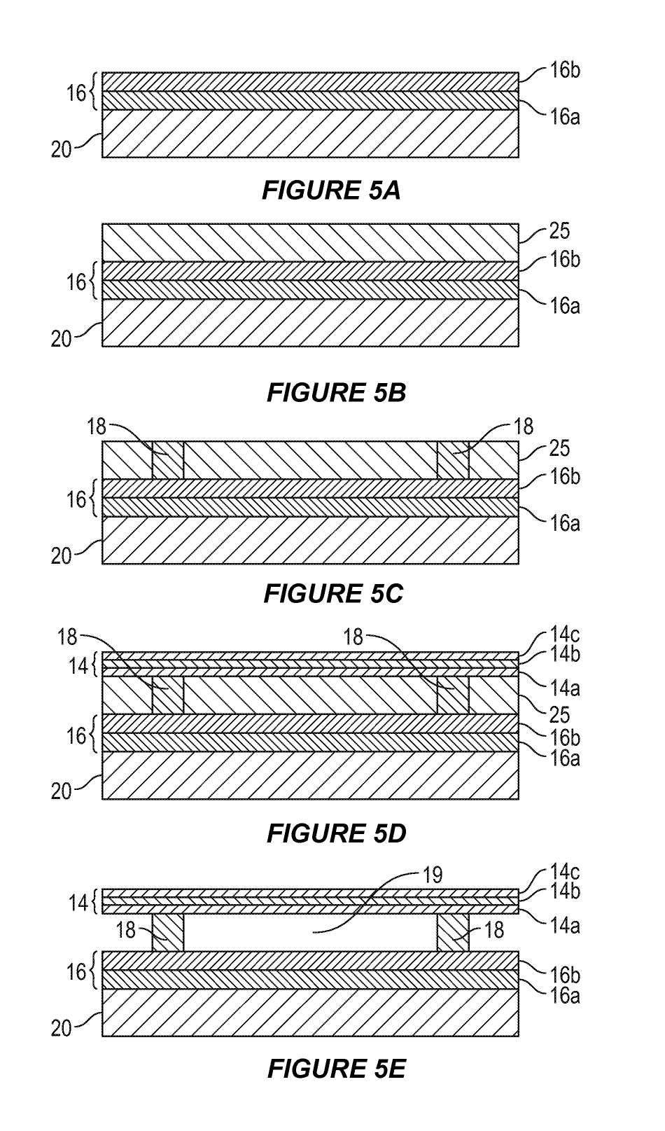

FIG. 4 is a flow diagram illustrating a manufacturing process 80 for an IMOD display or display element. FIGS. 5A-5E are cross-sectional illustrations of various stages in the manufacturing process 80 for making an IMOD display or display element. In some implementations, the manufacturing process 80 can be implemented to manufacture one or more EMS devices, such as IMOD displays or display elements. The manufacture of such an EMS device also can include other blocks not shown in FIG. 4. The process 80 begins at block 82 with the formation of the optical stack 16 over the substrate 20. FIG. 5A illustrates such an optical stack 16 formed over the substrate 20. The substrate 20 may be a transparent substrate such as glass or plastic such as the materials discussed above with respect to FIG. 1. The substrate 20 may be flexible or relatively stiff and unbending, and may have been subjected to prior preparation processes, such as cleaning, to facilitate efficient formation of the optical stack 16. As discussed above, the optical stack 16 can be electrically conductive, partially transparent, partially reflective, and partially absorptive, and may be fabricated, for example, by depositing one or more layers having the desired properties onto the transparent substrate 20.

In FIG. 5A, the optical stack 16 includes a multilayer structure having sub-layers 16a and 16b, although more or fewer sub-layers may be included in some other implementations. In some implementations, one of the sub-layers 16a and 16b can be configured with both optically absorptive and electrically conductive properties, such as the combined conductor/absorber sub-layer 16a. In some implementations, one of the sub-layers 16a and 16b can include molybdenum-chromium (molychrome or MoCr), or other materials with a suitable complex refractive index. Additionally, one or more of the sub-layers 16a and 16b can be patterned into parallel strips, and may form row electrodes in a display device. Such patterning can be performed by a masking and etching process or another suitable process known in the art. In some implementations, one of the sub-layers 16a and 16b can be an insulating or dielectric layer, such as an upper sub-layer 16b that is deposited over one or more underlying metal and/or oxide layers (such as one or more reflective and/or conductive layers). In addition, the optical stack 16 can be patterned into individual and parallel strips that form the rows of the display. In some implementations, at least one of the sub-layers of the optical stack, such as the optically absorptive layer, may be quite thin (e.g., relative to other layers depicted in this disclosure), even though the sub-layers 16a and 16b are shown somewhat thick in FIGS. 5A-5E.

The process 80 continues at block 84 with the formation of a sacrificial layer 25 over the optical stack 16. Because the sacrificial layer 25 is later removed (see block 90) to form the cavity 19, the sacrificial layer 25 is not shown in the resulting IMOD display elements. FIG. 5B illustrates a partially fabricated device including a sacrificial layer 25 formed over the optical stack 16. The formation of the sacrificial layer 25 over the optical stack 16 may include deposition of a xenon difluoride (XeF₂)-etchable material such as molybdenum (Mo) or amorphous silicon (Si), in a thickness selected to provide, after subsequent removal, a gap or cavity 19 (see also FIG. 5E) having a desired design size. Deposition of the sacrificial material may be carried out using deposition techniques such as physical vapor deposition (PVD, which includes many different techniques, such as sputtering), plasma-enhanced chemical vapor deposition (PECVD), thermal chemical vapor deposition (thermal CVD), or spin-coating.

The process 80 continues at block 86 with the formation of a support structure such as a support post 18. The formation of the support post 18 may include patterning the sacrificial layer 25 to form a support structure aperture, then depositing a material (such as a polymer or an inorganic material, like silicon oxide) into the aperture to form the support post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the support post 18 contacts the substrate 20. Alternatively, as depicted in FIG. 5C, the aperture formed in the sacrificial layer 25 can extend through the sacrificial layer 25, but not through the optical stack 16. For example, FIG. 5E illustrates the lower ends of the support posts 18 in contact with an upper surface of the optical stack 16. The support post 18, or other support structures, may be formed by depositing a layer of support structure material over the sacrificial layer 25 and patterning portions of the support structure material located away from apertures in the sacrificial layer 25. The support structures may be located within the apertures, as illustrated in FIG. 5C, but also can extend at least partially over a portion of the sacrificial layer 25. As noted above, the patterning of the sacrificial layer 25 and/or the support posts 18 can be performed by a masking and etching process, but also may be performed by alternative patterning methods.

The process 80 continues at block 88 with the formation of a movable reflective layer or membrane such as the movable reflective layer 14 illustrated in FIG. 5D. The movable reflective layer 14 may be formed by employing one or more deposition steps, including, for example, reflective layer (such as aluminum, aluminum alloy, or other reflective materials) deposition, along with one or more patterning, masking and/or etching steps. The movable reflective layer 14 can be patterned into individual and parallel strips that form, for example, the columns of the display. The movable reflective layer 14 can be electrically conductive, and referred to as an electrically conductive layer. In some implementations, the movable reflective layer 14 may include a plurality of sub-layers 14a, 14b and 14c as shown in FIG. 5D. In some implementations, one or more of the sub-layers, such as sub-layers 14a and 14c, may include highly reflective sub-layers selected for their optical properties, and another sub-layer 14b may include a mechanical sub-layer selected for its mechanical properties. In some implementations, the mechanical sub-layer may include a dielectric material. Since the sacrificial layer 25 is still present in the partially fabricated IMOD display element formed at block 88, the movable reflective layer 14 is typically not movable at this stage. A partially fabricated IMOD display element that contains a sacrificial layer 25 also may be referred to herein as an “unreleased” IMOD.

The process 80 continues at block 90 with the formation of a cavity 19. The cavity 19 may be formed by exposing the sacrificial material 25 (deposited at block 84) to an etchant. For example, an etchable sacrificial material such as Mo or amorphous Si may be removed by dry chemical etching by exposing the sacrificial layer 25 to a gaseous or vaporous etchant, such as vapors derived from solid XeF₂ for a period of time that is effective to remove the desired amount of material. The sacrificial material is typically selectively removed relative to the structures surrounding the cavity 19. Other etching methods, such as wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD display element may be referred to herein as a “released” IMOD.

Creep is the tendency of a solid material to move slowly or deform permanently under the influence of mechanical stresses. Creep is a time-dependent deformation mechanism that may or may not constitute a failure mode. MEMS devices may include one or more movable parts that may be subject to creep. MEMS devices can undergo deformation as a result of creep because of mechanical stresses and thermal energy. Such mechanical stresses may be below the yield strength of a material in the MEMS device, but over time and over elevated temperatures, the material will deform. Accordingly, mechanical actuation and thermal heating can cause atoms to diffuse around some of the layers of the MEMS device over time, eventually causing the MEMS device to fail. Creep resistance of the MEMS device can be increased by one or more of the following: reducing the operating temperature, reducing the applied stress levels, and changing the material.

In changing the composition of the material, the microstructure of the material may be controlled to limit the effects of creep. Deformation as a result of creep can be attributed to diffusional effects, such as the diffusion of atoms across grain boundaries. When the operating temperature increases, the thermal energy causes increased diffusion, thereby resulting in greater creep deformation. Solutions for limiting the mechanism of diffusional creep can include, for example, reducing the grain size of the material and making the material more mechanically robust.

Typically, some metallic layers and structures, especially those with low melting points or soft metal such as aluminum or gold, may be vulnerable to creep deformation due in part to its thermal and mechanical properties. Moreover, MEMS devices include movable parts that can undergo greater amounts of mechanical strain. Under elevated temperatures, the diffusion of atoms may increase, especially in regions exposed to more mechanical strain. Over time, this can lead to creep deformation that can result in device failure. Where movable parts include metallic layers and structures, these movable parts that are vulnerable to creep deformation may be strengthened to be more creep-resistant and more mechanically robust.

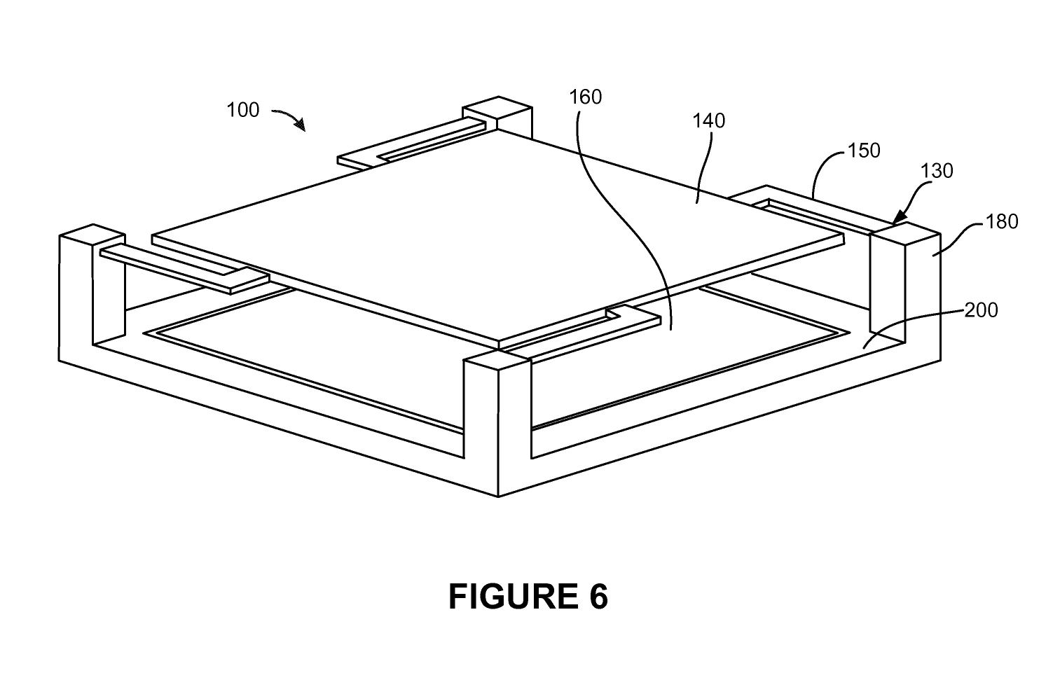

An example of a MEMS device can be a MEMS display device or MEMS display device element (e.g., pixel). In some implementations, the MEMS display device can include an IMOD, which is described with reference to FIGS. 1-5E. FIG. 6 shows a perspective view of an example MEMS display device having a movable reflective structure spaced apart from a stationary electrode by a gap. The MEMS display device 100 can include a substrate 200 and a stationary electrode 160 on the substrate 200. The MEMS display device 100 can further include a movable reflective structure 140 over the stationary electrode 160, where the movable reflective structure 140 and the stationary electrode 160 define a gap therebetween. The movable reflective structure 140 may be supported by one or more support structures 130, where the one or more support structures 130 may be between the substrate 200 and the movable reflective structure 140. In some implementations, the one or more support structures 130 may be symmetrically disposed around the movable reflective structure 140. In some implementations, the MEMS display device 100 can be an IMOD, such as a bistable IMOD, multi-state IMOD, or analog IMOD.

In some implementations, each of the one or more support structures 130 can include a tether or hinge 150 connected to a support post 180. The movable reflective structure 140 may be connected to each of the support posts 180 via tethers 150. In some implementations, the tethers 150 may be tangential to the movable reflective structure 140 and can reduce the residual stress in the MEMS display device 100. Other configurations for tethers 150, including straight, curved, or folded, are also possible. In some implementations, the tethers 150 may be made of metals, such as aluminum, aluminum-titanium, or aluminum-zirconium, or other materials such as amorphous or polycrystalline silicon, oxides, nitrides, and oxynitrides. In some implementations, the tethers 150 may include the same or substantially the same material as the movable reflective structure 140.

The substrate 200 can be made of any suitable substrate materials, including a substantially transparent material, such as glass or plastic. Substantial transparency as used herein may be defined as transmittance of visible light of about 70% or more, such as about 80% or more or about 90% or more. Glass substrates (sometimes referred to as glass plates or panels) may be or include a borosilicate glass, a soda lime glass, photoglass, quartz, Pyrex or other suitable glass material. A non-glass substrate can be used, such as a polycarbonate, acrylic, polyimide, polyethylene terephthalate (PET) or polyether ether ketone (PEEK) substrate. In some implementations, the substrate 200 can have dimensions of a few microns to hundreds of microns. For example, the substrate 200 can have a thickness between about 10 microns and about 1100 microns.

The stationary electrode 160 on the substrate 200 may be electrically conductive or include an electrically conductive layer. In some implementations, the stationary electrode 160 may be part of an optical stack. The optical stack can be at least partially absorbing of visible light and can include an optically absorbing material. An optically absorbing material can include, for example, a molybdenum-chromium compound having a thickness between about 20 Å and about 100 Å. The optical stack can include a plurality of sub-layers and can be configured similarly to the optical stack 16 in FIGS. 3A-3E.

The movable reflective structure 140 can be referred to as a movable electrode or a mirror. The movable reflective structure 140 can be electrically conductive or include an electrically conductive layer. The movable reflective structure 140 can include a plurality of layers (not shown), including but not limited to a reflective layer and an optical layer. The reflective layer can include a material that is configured to substantially reflect visible light, where the reflectance can be about 70% or more, such as about 80% or more or about 90% or more. In some implementations, the reflective layer can provide a mirror for interferometrically modulating light with the optically absorbing material in the stationary electrode 160.

In some implementations, the movable reflective structure 140 can include a reflective layer and a deformable layer, where the optical properties of the movable reflective structure 140 can be decoupled from its mechanical properties. The reflective layer can include a plurality of sub-layers, including but not limited to a reflective sub-layer, a dielectric sub-layer, and a metal sub-layer. The reflective sub-layer can have a thickness between about 100 Å and about 500 Å and can include aluminum or aluminum alloy. If a dielectric sub-layer is included in the reflective layer, the dielectric sub-layer can have a thickness between about 4000 Å and about 40000 Å to provide structural rigidity to the movable reflective structure 140. The dielectric sub-layer can include any suitable dielectric material such as nitrous oxide, silicon dioxide, silicon oxynitride, and silicon nitride. If a metal sub-layer is included in the reflective layer, the metal sub-layer can have a thickness between about 100 Å and about 1000 Å and can include aluminum, copper, aluminum-copper alloy, aluminum-titanium alloy, aluminum-zirconium alloy, or other electrically conductive material.

The movable reflective structure 140 may be configured to electrostatically actuate towards the stationary electrode 160 when a voltage is applied. The one or more support structures 130 may bend and cause the movable reflective structure 140 to deflect towards the stationary electrode 160. In some implementations, the movable reflective structure 140 can remain parallel or substantially parallel to the stationary electrode 160 during actuation. As the movable reflective structure 140 moves or otherwise deflects towards the stationary electrode 160, a gap distance between the movable reflective structure 140 and the stationary electrode 160 can influence the reflective properties of the MEMS display device 100. For example, different gap distances can reflect different wavelengths of light through the substrate 200, which gives the appearance of different colors.

The repeated movement of the movable reflective structure 140 and the one or more support structures 130 can cause the MEMS display device 100 to undergo several cycles of stress. The movable reflective structure 140 and the one or more support structures 130 can be made of metallic materials. In addition, during the operating lifetime of the MEMS display device 100, the MEMS display device 100 can be exposed to elevated temperatures. Thus, the MEMS display device 100 may be vulnerable to creep deformation and potential mechanical failure.

In some implementations, the one or more support structures 130 may be deformable. The one or more support structures 130 may permit the movable reflective structure 140 to actuate in the MEMS display device 100. Over time, the creep behavior in the movable reflective structure 140 can cause the one or more support structures 130 to become unable to restore to its original position after actuation. This can lead to poor image retention and device failure in the MEMS display device 100. For example, device failure can occur at connection points between the tethers 150 and the movable reflective structure 140 as a result of creep.

To increase the creep resistance of movable parts in the MEMS display device 100, the materials of the movable parts can be changed to provide greater creep resistance and mechanical strength. The movable reflective structure 140 can include aluminum or aluminum alloy. Examples of creep-resistant aluminum alloys can include but is not limited to aluminum-copper, aluminum-scandium, and aluminum-zirconium. The aluminum or aluminum alloy can serve as a reflective material for the movable reflective structure 140, where the reflectance of the movable reflective structure 140 can reflect greater than about 80% of visible light. The aluminum or aluminum alloy can serve as an electrically conductive material for the movable reflective structure 140, where the sheet resistance of the movable reflective structure 140 can be less than about 1, 10, or 100 ohms per square.

The aluminum or aluminum alloy may provide some resistance against creep, but stress control in the movable reflective layer 140 may be difficult with the aluminum or aluminum alloy. For example, when the movable reflective layer 140 in the MEMS display device 100 is subject to subsequent deposition and annealing, the movable reflective layer 140 with aluminum or aluminum alloy can end up with increased tensile stress. For example, the movable reflective layer 140 with aluminum or aluminum alloy can have a tensile stress of greater than about 500 MPa after annealing at 350° C.

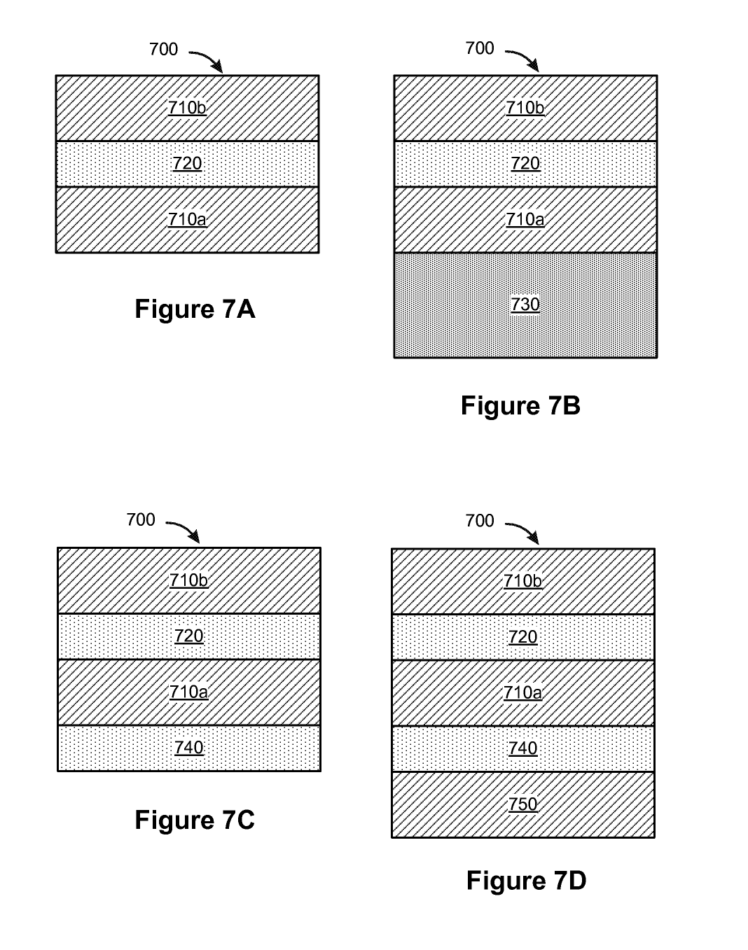

FIGS. 7A-7D show cross-sectional side views of example thin film stacks for movable reflective structures. However, it is understood that such thin film stacks may be incorporated not only in movable reflective structures, but in other movable parts, such as support structures (e.g., hinges). A more creep-resistant and mechanically robust aluminum or aluminum alloy can be formed by doping a transition metal into the aluminum or aluminum alloy. How the transition metal is doped into the aluminum or aluminum alloy can be achieved by providing a thin film stack as shown in FIGS. 7A-7D and annealing the thin film stack. As a result, the aluminum or aluminum alloy can be doped with the transition metal upon annealing.

FIG. 7A shows a cross-sectional side view of an example thin film stack for a movable reflective structure with a transition metal layer sandwiched between two reflective layers. The thin film stack 700 can include a bottom layer 710a, a top layer 710b over the bottom layer 710a, and a middle layer 720 between the bottom layer 710a and the top layer 710a. The top and bottom layers 710a, 710b can constitute reflective layers and the middle layer 720 can constitute a transition metal layer. In some implementations, the reflective layers 710a, 710b may be substantially identical in composition and thickness with each other. The transition metal layer 720 may be in contact with at least one of the reflective layers 710a, 710b. In some implementations, the transition metal layer 720 may be in contact with both of the reflective layers 710a, 710b.

The thin film stack 700 may also be referred to as an annealed multilayer thin film stack. The thin film stack 700 can have a total thickness of less than about 5 microns, or between about 50 nm and about 3 microns. The transition metal layer 720 can have a thickness of less than about 20% of the total thickness of the thin film stack 700, or less than about 10% of the total thickness of the thin film stack 700. For example, the reflective layers 710a, 710b can each have a thickness equal to or greater than about 20 nm, and the transition metal layer 720 can have a thickness of less than about 5 nm. The reflective layers 710a, 710b can each include aluminum or aluminum alloy, and the transition metal layer 720 can include at least one of: zirconium, scandium, ruthenium, titanium, tantalum, molybdenum, and chromium. For example, the transition metal can include zirconium.

The transition metal layer 720 upon doping into the reflective layers 710a, 710b, can improve creep resistance and reduce the stress of the reflective layers 710a, 710b while minimizing degradation of the optical and electrical properties of the reflective layers 710a, 710b. A movable reflective structure incorporating the thin film stack 700 can have a relatively low stress value, such as a stress value of less than about 200 MPa, or less than 100 MPa. Furthermore, the movable reflective structure incorporating the thin film stack 700 can have a sufficiently high reflectance of visible light, such as a reflectance of greater than about 80% or greater than about 90%. The reduced stress value and the sufficiently high reflectance value can be achieved even after annealing the thin film stack 700. In some implementations, the movable reflective structure incorporating the thin film stack 700 can have a relatively low sheet resistance value, such as less than about 1, 10 or 100 ohms per square.

Incorporating a transition metal layer 720 between two reflective layers 710a, 710b permits diffusion of transition metal atoms to dope the reflective layers 710a, 710b with the transition metal. Upon annealing, atoms of the transition metal may diffuse into the two reflective layers 710a, 710b from both sides of the transition metal layer 720. The thickness of the transition metal layer 720 and the annealing conditions can influence how the reflective layers 710a, 710b are doped. Each of the reflective layers 710a, 710b can be doped with about 0.1 atomic % to about 10 atomic % of the transition metal, or with about 0.5 atomic % to about 5 atomic % of the transition metal. The doped thin film stack 700 can provide greater creep resistance and stress control.

In some implementations, the thin film stack 700 can be doped to further include less than 20 atomic % of one or both of oxygen and nitrogen, or between about 1 atomic % and about 20 atomic % of one or both of oxygen and nitrogen. The thin film stack 700 can be doped with oxygen and/or nitrogen to further improve creep resistance and reduce stress. The aluminum or aluminum alloy may react with oxygen and/or nitrogen to form aluminum oxide, aluminum nitride, or aluminum oxynitride. When doping with one or both of oxygen and nitrogen, oxygen and nitrogen atoms can be provided at the grain boundaries of the reflective layers 710a, 710b to limit grain growth and limit the diffusion of atoms across the grain boundaries. The doping can occur by flowing oxygen and nitrogen gas during the aluminum or aluminum alloy deposition (e.g., sputter deposition). For example, oxygen gas can be flowed at less than about 5 standard cubic centimeters per minute (sccm), and nitrogen gas can be flowed at less than about 10 sccm while the sputtering gas such as argon or krypton can be ranged from 50 sccm to 100 sccm or 200 sccm or more.

The movable reflective structure incorporating the thin film stack 700 can be part of a “thin” film reflective structure or a “thick” film reflective structure. In implementations for a “thin” film reflective structure, the reflective layers 710a, 710b can be relatively thin, such as each having a thickness between about 10 nm and about 50 nm. However, the movable reflective structure in such implementations can include dielectric layers, where the dielectric layers can provide structural rigidity to the movable reflective structure and can each have a thickness between about 400 nm and about 4000 nm. In implementations for a “thick” film reflective structure, the reflective layers 710a, 710b can be relatively thick, such as each having a thickness between about 100 nm and about 1000 nm. The movable reflective structure in such implementations may or may not include dielectric layers to provide structural rigidity.

FIG. 7B shows a cross-sectional side view of an example movable reflective structure including a thin film stack over an optical layer. As discussed earlier herein, the movable reflective structure can include a plurality of layers. Examples of such layers can include reflective layers, deformable layers, metal layers, optical layers, and dielectric layers. The thin film stack 700 may be incorporated in a movable reflective structure having one or more of the aforementioned layers. The thin film stack 700 includes the middle layer 720 sandwiched between the bottom layer 710a and the top layer 710b. As shown in the example in FIG. 7B, the thin film stack 700 is formed, positioned, or placed on an optical layer 730. In some implementations, the optical layer 730 can include titanium oxide or zirconium oxide and can have a thickness between about 100 nm and about 500 nm.

FIG. 7C shows a cross-sectional side view of an example thin film stack for a movable reflective structure with an additional transition metal layer. FIG. 7D shows a cross-sectional side view of an example thin film stack for a movable reflective structure with an additional transition metal layer and an additional reflective layer. Additional layers in the thin film stack 700 may provide greater control and tunability of mechanical, optical, and electrical properties of the movable reflective structure incorporating the thin film stack 700. In some implementations, additional layers may provide a more balanced thin film stack 700 in terms of stress.

In FIG. 7C, the thin film stack 700 includes the middle layer 720 sandwiched between the bottom layer 710a and the top layer 710b. The thin film stack 700 can further include a first layer 740, where the first layer 740 is below the bottom layer 710a. In some implementations, the first layer 740 can be substantially identical in composition and thickness with the middle layer 720. Hence, the first layer 740 can further dope the aluminum or aluminum alloy in the bottom layer 710a with a transition metal to further control the mechanical properties of the movable reflective structure incorporating the thin film stack 700.

In FIG. 7D, the thin film stack 700 includes the middle layer 720 sandwiched between the bottom layer 710a and the top layer 710b, and further includes the first layer 740 below the bottom layer 710a and a second layer 750 below the first layer 740. In some implementations, the second layer 750 can be substantially identical in composition and thickness with one or both of the bottom layer 710a and the top layer 710b. In alternative implementations, the second layer 750 can be different in composition and/or thickness with one or both of the bottom layer 710a and the top layer 710b. The transition metal can further dope the aluminum or aluminum alloy in the bottom layer 710a, the top layer 710b, and the second layer 750. The additional layers in the thin film stack 700 are not limited to the configurations shown in FIGS. 7C and 7D, but may be arranged in different configurations and may include even more or fewer layers.

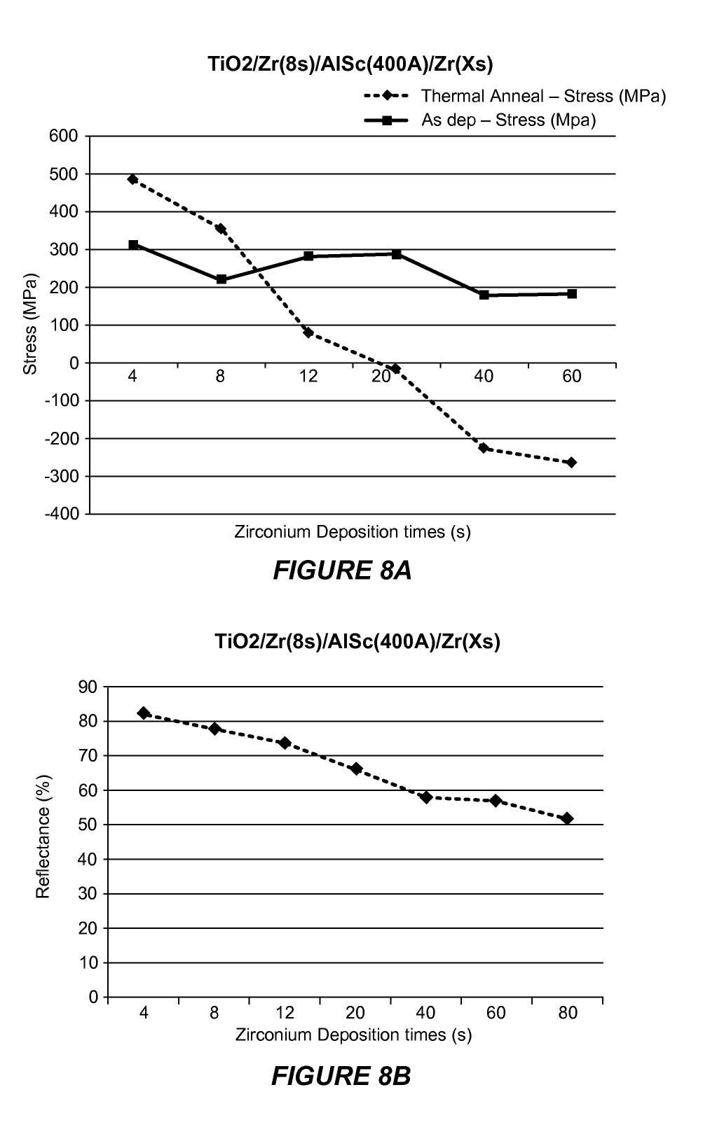

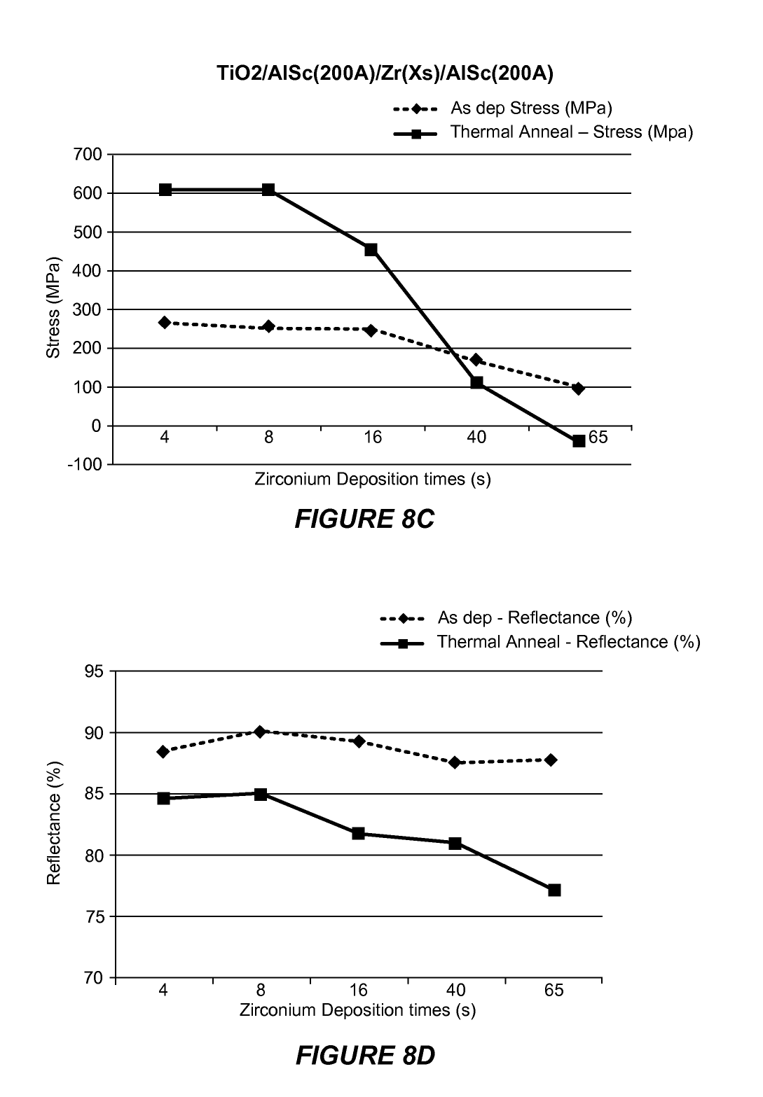

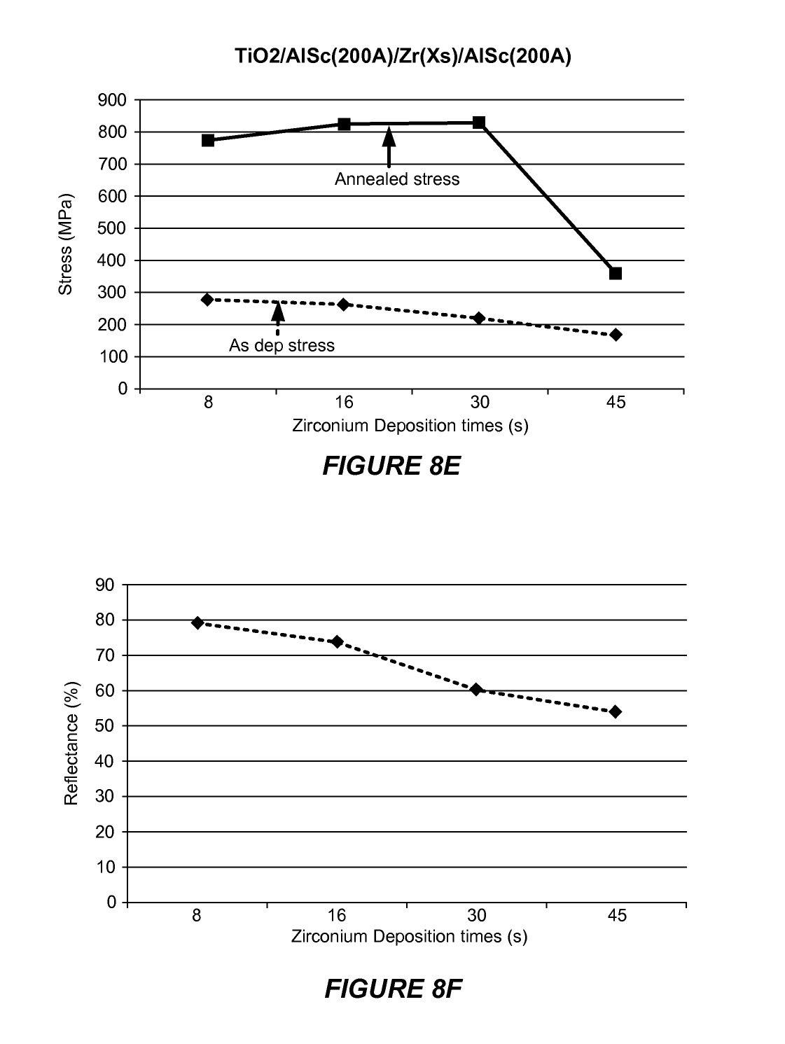

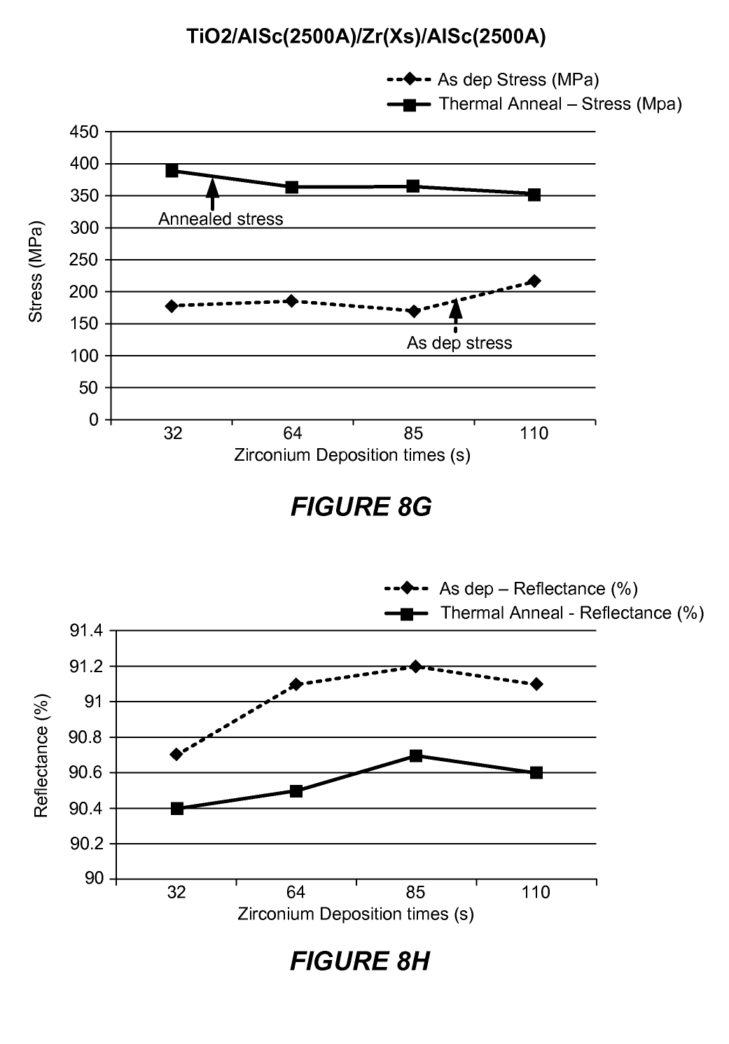

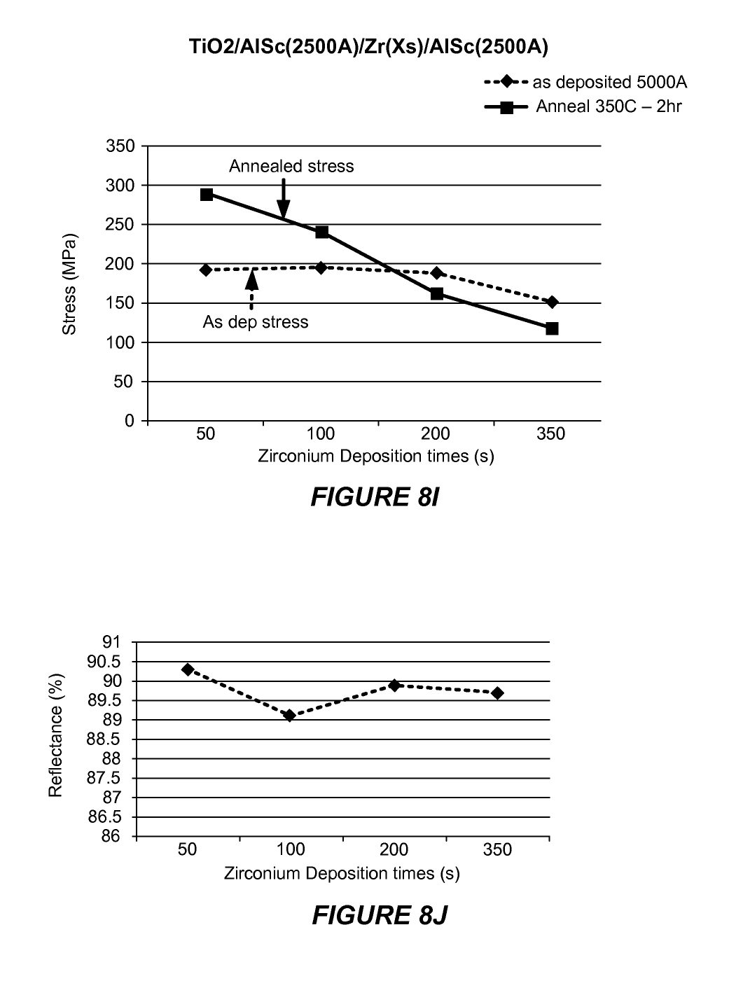

Different configurations of the thin film stack, different thicknesses of the transition metal layer, and different annealing conditions can influence the mechanical, optical, and electrical properties of the movable reflective structure, as shown in FIGS. 8A-8J. In FIGS. 8A-8J, data is provided measuring the stress and reflectance of various thin film stack configurations. Some thin film stacks are exposed to different annealing conditions. The annealing can cause the transition metal atoms to dope the aluminum or aluminum alloy through a thermal diffusion process. Stress and reflectance values are measured with respect to varying deposition times for zirconium. Zirconium can provide increased creep resistance and control stress. Without being limited by theory, zirconium atoms may readily precipitate in the grain boundaries to limit diffusion of atoms as well as limit grain growth.

FIG. 8A shows a graph illustrating stress of a movable reflective structure as a function of the zirconium deposition times, where the movable reflective structure includes an aluminum-scandium layer sandwiched between two zirconium layers. FIG. 8B shows a graph illustrating reflectance of the movable reflective structure from FIG. 8A as a function of the zirconium deposition times. The movable reflective structure includes a bottom layer of zirconium over the optical layer and having a thickness corresponding to 8 seconds of deposition time, a middle layer of aluminum-scandium over the bottom layer and having a thickness of 4000 nm, and a top layer of zirconium having a thickness corresponding to variable deposition times. The movable reflective structure is subjected to a thermal anneal at about 350° C. for 250 seconds in 1 standard liters per minute (slm) of nitrogen gas. As the zirconium deposition times increase (i.e., increasing zirconium thickness), the stress in the movable reflective structure decreases. For as-deposited films, the stress does not exhibit a significant decrease. This can show that the zirconium atoms do not diffuse very much into the aluminum-scandium layer unless the movable reflective structure is annealed. For annealed films, the stress can change dramatically and even cross over from tensile to compressive stress. This may indicate the tunability of the stress by thermal annealing. Furthermore, the increasing zirconium thickness corresponds to decreasing reflectance. In fact, the reflectance is less than about 80% after 8 seconds of zirconium deposition, and less than 60% after 40 seconds of zirconium deposition. Such a thin film stack configuration for a display may not provide sufficient image quality.

FIG. 8C shows a graph illustrating stress of a movable reflective structure as a function of zirconium deposition times, where the movable reflective structure includes zirconium sandwiched between two aluminum alloy layers. FIG. 8D shows a graph illustrating reflectance of the movable reflective structure from FIG. 8C as a function of the zirconium deposition times. The movable reflective structure includes a bottom layer of aluminum-scandium over the optical layer and having a thickness of 20 nm, a middle layer of zirconium having a thickness corresponding to variable deposition times, and a top layer of aluminum-scandium having a thickness of 20 nm. The movable reflective structure is subjected to a thermal anneal at about 350° C. for 250 seconds in 1 slm of nitrogen gas. As the zirconium deposition time increases, the stress decreases for both as-deposited conditions and after annealing. The stress may be relatively low and similar under both conditions. This can mean that the grain structure does not significantly change even after annealing, meaning that the microstructure may be thermally stable. However, the reflectance decreases after anneal and decreases with increasing zirconium thickness, where the reflectance can drop below 85%.

FIG. 8E shows a graph illustrating stress of a movable reflective layer as a function of the zirconium deposition times, where the movable reflective structure includes zirconium sandwiched between two aluminum alloy layers. FIG. 8F shows a graph illustrating reflectance of the movable reflective structure from FIG. 8E as a function of zirconium deposition times. The movable reflective structure includes a bottom layer of aluminum-scandium over the optical layer and having a thickness of 20 nm, a middle layer of zirconium having a thickness corresponding to variable deposition times, and a top layer of aluminum-scandium having a thickness of 20 nm. The movable reflective structure is subjected to different annealing conditions, where the movable reflective structure is thermally annealed for 2 hours at about 350° C. in nitrogen gas. Under such annealing conditions with a longer anneal time, the stress in the movable reflective structure becomes considerably high. The stress in the movable reflective structure without annealing decreases slightly. This can suggest a change in grain structure under such annealing conditions. The reflectance also decreases considerably after anneal and decreases with increasing zirconium thickness. Though not shown, the sheet resistance of the movable reflective structure increases from 1.5 ohms per square to 13.5 ohms per square as the zirconium deposition times increase from 8 seconds to 45 seconds. Overall, this shows that increasing the zirconium thickness can degrade the reflectance and electrical properties of the movable reflective structure, and incorporating zirconium in such a thin film stack configuration does not improve the mechanical properties with a longer anneal time.

FIG. 8G shows a graph illustrating stress of a movable reflective structure as a function of zirconium deposition times, where the movable reflective structure includes zirconium sandwiched between two thick aluminum alloy layers. FIG. 8H shows a graph illustrating reflectance of the movable reflective structure from FIG. 8G as a function of zirconium deposition times. Here, the movable reflective structure includes a bottom layer of aluminum-scandium over the optical layer and having a thickness of 250 nm, a middle layer of zirconium having a thickness corresponding to variable deposition times, and a top layer of aluminum-scandium having a thickness of 250 nm. The movable reflective structure is subjected to a thermal anneal at about 350° C. for 250 seconds in 1 slm of nitrogen gas. With thicker aluminum-scandium layers, the reflectance of the movable reflective structure does not degrade, but remains above 90% reflectance of visible light even after annealing. However, while the stress remains relatively the same under both as-deposited conditions and after annealing, the stress after annealing is greater than about 350 MPa.

FIG. 8I shows a graph illustrating stress of a movable reflective structure as a function of zirconium deposition times, where the movable reflective structure includes zirconium sandwiched between two thick aluminum alloy layers. FIG. 8J shows a graph illustrating reflectance of the movable reflective structure from FIG. 8I as a function of zirconium deposition times. The movable reflective structure includes a bottom layer of aluminum-scandium over the optical layer and having a thickness of 250 nm, a middle layer of zirconium having a thickness corresponding to variable deposition times, and a top layer of aluminum-scandium having a thickness of 250 nm. The movable reflective structure is subjected to an own anneal at about 350° C. for 2 hours in nitrogen gas. As the zirconium deposition times increased, the stress decreased in both as-deposited conditions and after annealing, where the stress was below 200 MPa after a zirconium deposition time of 200 seconds. In fact, the stress does not change much between as-deposited conditions and after annealing, which can indicate that not much structural changes occur irrespective of longer annealing times. The reflectance of the movable reflective structure is greater than 89% even after annealing. Though not shown, the sheet resistance of the movable reflective structure is measured to be about 0.052 ohms per square, showing that the electrical properties do not degrade irrespective of longer anneal times.

Data in FIGS. 8A-8J show that the incorporation of a layer of zirconium between two layers of aluminum-scandium can control stress in the movable reflective structure. Some configurations of the movable reflective structure show stress even less than 150 MPa after annealing at 350° C. for 2 hours. Furthermore, some configurations of the movable reflective structure provided a reflectance greater than 85% and some configurations even greater than 90%, showing that such configurations can meet desired optical standards. Some configurations of the movable reflective structure provided a sheet resistance of less than 1 or less than 10 ohms per square, indicating that such configurations can maintain desired electrical properties even after annealing.

In some implementations, doping the aluminum or aluminum alloy layers with oxygen and/or nitrogen can further improve the mechanical robustness of the movable reflective structure. Table 1 shows stress data for a movable reflective structure including an aluminum alloy mirror, where the stress values vary depending on the amount of nitrogen or oxygen gas introduced with the aluminum alloy. The stress values are taken before annealing and after annealing at about 350° C. for 3 hours. Oxygen and/or nitrogen gases are flowed in low amounts during the deposition of the aluminum alloy. For example, the oxygen and nitrogen gases can be introduced during sputtering of the aluminum alloy to form precipitates of aluminum oxide, aluminum nitride, or aluminum oxynitride. An inert carrier gas such as argon is also be flowed simultaneously.

TABLE 1

| | | Oxygen | Stress (MPa) | |
|---|---|---|---|---|
| Argon (sccm) | Nitrogen (sccm) | (sccm) | As-deposited | Anneal |
| 33 | 0 | 0 | 45 | 710 |
| 33 | 0 | 3 | −168.8 | 551 |
| 33 | 0 | 6 | −328.1 | 573 |
| 33 | 0 | 10 | −195.1 | 476 |
| 33 | 10 | 0 | 64.2 | 427 |
| 33 | 20 | 0 | 168 | 181 |
| 33 | 30 | 0 | 246 | 196 |
| 33 | 40 | 0 | 204 | 164 |
| 33 | 10 | 3 | 0.8 | 146 |
| 33 | 10 | 10 | −18.4 | 47 |
| 33 | 30 | 3 | −32.6 | −10 |
| 33 | 30 | 10 | −13.7 | 27 |
| 33 | 40 | 3 | −21.1 | −77 |

The flow rates of nitrogen and oxygen gas can be adjusted to control the stress of the movable reflective structure having an aluminum alloy mirror. The flow rate of oxygen gas can be less than about 5 sccm and the flow rate of nitrogen gas can be less than about 10 sccm. In some implementations, the flow rate of oxygen gas can be less than about 4 sccm, and the flow rate of nitrogen gas can be less than about 5 sccm. As shown in Table 1, introduction of oxygen and nitrogen can reduce the stress of the movable reflective structure to be less than 100 MPa. Additionally, the sheet resistance of the movable reflective structure doped with oxygen and nitrogen is about 1.2 ohms per square for a movable reflective structure having a thickness of 40 nm. The movable reflective structure doped with oxygen and nitrogen can improve the stress of creep-resistant films while maintaining a relatively low sheet resistance.

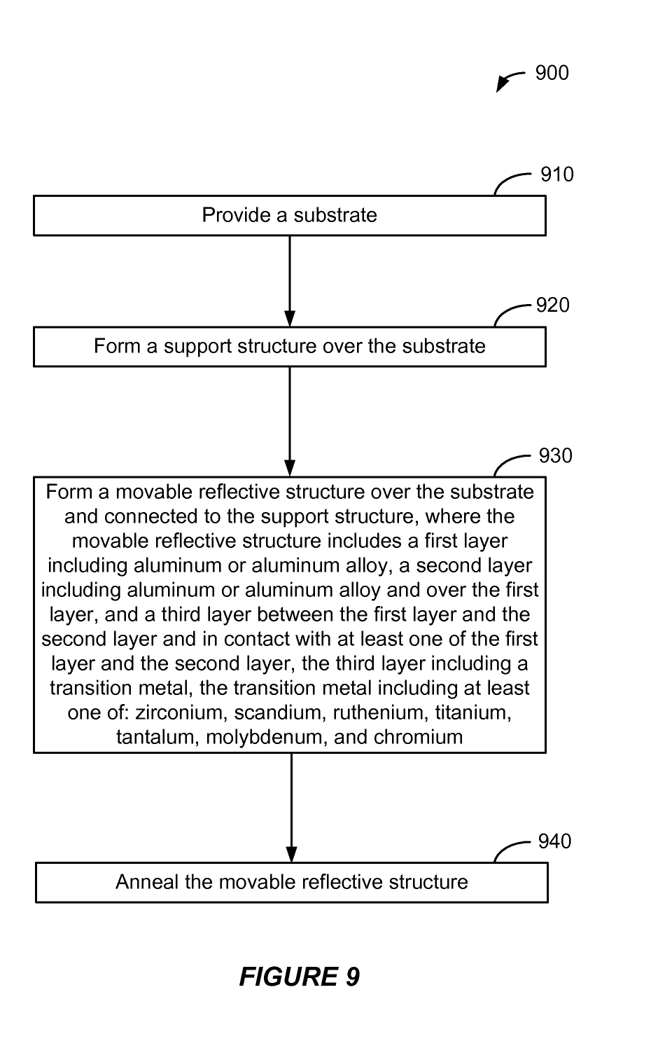

FIG. 9 is a flow diagram of an example method of manufacturing a MEMS display device. The process 900 may be performed in a different order or with different, fewer or additional operations.

At block 910, a substrate is provided. The substrate can include any suitable substrate material, such as glass or plastic. In some implementations, the substrate material can be substantially transparent to visible light. One or more display elements may be formed on the substrate for the MEMS display device. In some implementations, the one or more display elements can include an active matrix OLED, shutter-based light modulator, or IMOD. Each of the display elements can be part of a pixel in the display device. In some implementations, the process 900 can further include forming a stationary electrode or optical stack over the substrate, where the stationary electrode or optical stack can include an electrically conductive material.

At block 920, a support structure is formed over the substrate. In some implementations, the support structure can include a plurality of tethers or hinges symmetrically disposed around the edges of a movable reflective structure. The support structure can be formed on the substrate and configured to support a movable reflective structure. The support structure can be formed of a metal, such as aluminum or titanium, or other materials, such as oxides, nitrides, and oxynitrides. In some implementations, the support structure can include materials identical or substantially identical with the materials of the movable reflective structure. Thus, the support structure can include aluminum or aluminum alloy. The support structure may be bendable to permit the actuation of the movable reflective structure towards the substrate. In some implementations, the support structure can include a support post and a tether connected to the support post, where tether is connected to the movable reflective structure. The tether can be made of a flexible material while the support posts can be made of a relatively rigid material.

At block 930, a movable reflective structure is formed over the substrate and connected to the support structure, where the movable reflective structure includes a first layer including aluminum or aluminum alloy, a second layer including aluminum or aluminum alloy and over the first layer, and a third layer between the first layer and the second layer where the third layer is in contact with at least one of the first layer and the second layer. The third layer includes a transition metal, where the transition metal includes at least one of zirconium, scandium, ruthenium, titanium, tantalum, molybdenum, and chromium.

The movable reflective structure can constitute a movable electrode or mirror that is separated from the stationary electrode by a gap. The movable reflective structure can be configured to move across the gap towards the stationary electrode by electrostatic force. The movable reflective structure can be part of a pixel of the MEMS display device. Pixels of the MEMS display device can be arranged as an array to form a display. A gap distance between the movable reflective structure and the stationary electrode can reflect a certain wavelength of light to give the appearance of a particular color.

In some implementations, forming the movable reflective structure can include depositing the first layer over the substrate, depositing the third layer on the first layer, and depositing the second layer on the third layer. The movable reflective structure can form a thin film stack having a transition metal layer sandwiched between two aluminum or aluminum alloy layers. Each of the deposition steps may be subsequently followed by masking, patterning, etching, or planarization steps. Each of the layers can be deposited using deposition techniques known in the art, such as PVD, CVD, PECVD, ALD, and spin-coating. PVD processes can include pulsed laser deposition, sputter deposition, electron beam physical vapor deposition, and evaporative deposition. In some implementations, the movable reflective structure can further include an optical layer of titanium oxide, where the first layer is formed over the optical layer.

In some implementations, the first layer and the second layer of the movable reflective structure can be substantially identical in composition and thickness. The composition of the first layer and the second layer can include aluminum, such as pure aluminum, aluminum-scandium, aluminum-zirconium, or aluminum-copper. The thickness of the first layer and the second layer can each be equal to or greater than about 20 nm, such as between about 20 nm and about 400 nm. The thickness of the third layer can be less than about 5 nm. In some implementations, the thickness of the third layer can be about 10% or less than a total thickness of the movable reflective structure.

In some implementations, depositing the first layer can include doping the first layer with one or both of oxygen and nitrogen, and depositing the second layer can include doping the second layer with one or both of oxygen and nitrogen. Doping the first and second layers with oxygen and/or nitrogen can include flowing oxygen and/or nitrogen gas during reactive sputtering of aluminum or aluminum alloy. In some implementations, the flow rate of oxygen gas can be less than about 5 sccm and the flow rate of nitrogen gas can be less than about 10 sccm.

In some implementations, the process 900 further includes depositing a fourth layer between the substrate and the first layer, where the fourth layer is substantially identical in composition and thickness with the third layer. Therefore, another transition metal layer can be incorporated in the thin film stack of the movable reflective structure. In some implementations, the fourth layer can provide a more balanced structure in terms of stress.

In some implementations, the process 900 can further include depositing a fifth layer between the substrate and the fourth layer, where the fifth layer is substantially identical in thickness and composition with the first layer and the second layer. The fifth layer can include aluminum or aluminum alloy, and can have a thickness equal to or greater than about 20 nm. In some implementations, the fifth layer can provide a more balanced structure in terms of stress.

At block 940, the movable reflective structure is annealed. By annealing the movable reflective structure, the first layer and the second layer can be doped with the transition metal. Upon annealing, the transition metal can diffuse from both sides so that the first layer can be doped and the second layer can be doped with the transition metal. In some implementations, the first and the second layers can each be doped with about 0.1 atomic % to about 10 atomic % of the transition metal, or with about 0.5 atomic % to about 5 atomic % of the transition metal. In some implementations, the temperature during anneal can be between about 100° C. and about 600° C. It may be desirable to control the stress so that the stress of the movable reflective structure under as-deposited conditions and after annealing may be relatively similar. That way, the microstructure of the movable reflective structure can be thermally stable.

Such an annealed thin film stack in the movable reflective structure can reduce stress in a creep-resistant movable reflective structure, where the stress can be less than about 200 MPa or less than about 100 MPa. The annealed thin film stack can strengthen the mechanical robustness of the movable reflective structure without considerably degrading the optical and electrical properties of the movable reflective structure. For example, the sheet resistance of the movable reflective structure can be less than about 1 or less than about 10 ohms per square and the reflectance of the movable reflective structure can be greater than about 80%.

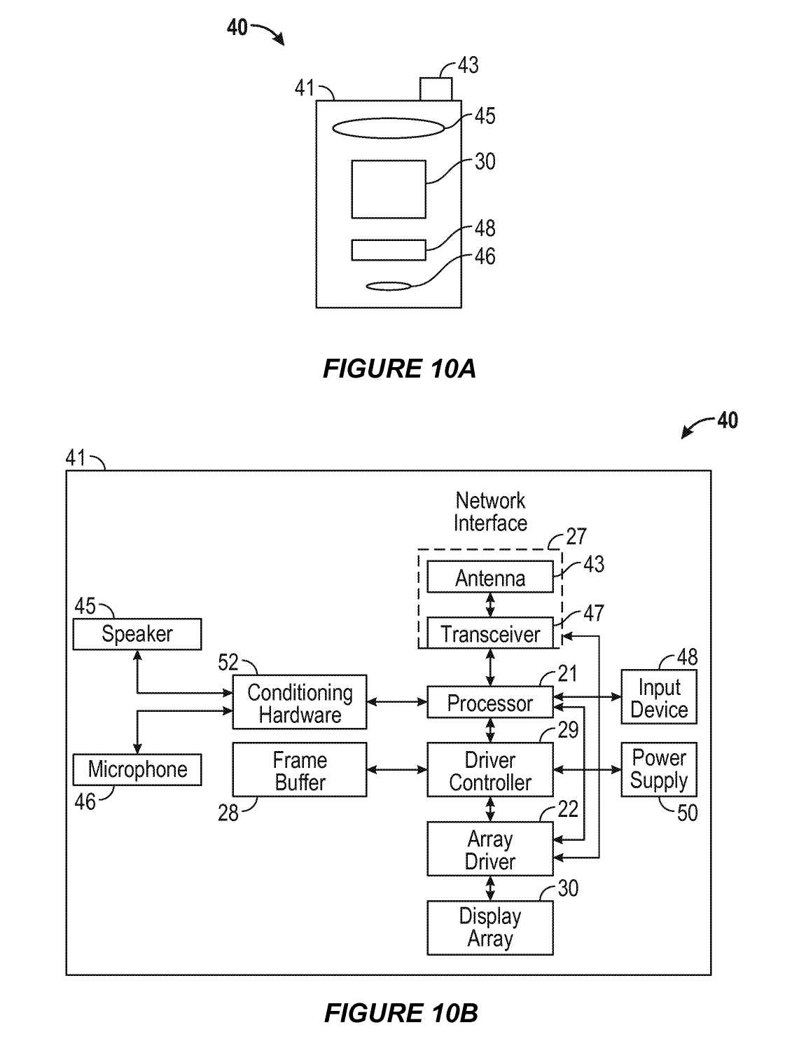

FIGS. 10A and 10B are system block diagrams illustrating a display device 40 that includes a plurality of MEMS display elements, such as the MEMS display device shown in FIG. 6. The display device 40 can be, for example, a smart phone, a cellular or mobile telephone. However, the same components of the display device 40 or slight variations thereof are also illustrative of various types of display devices such as televisions, computers, tablets, e-readers, hand-held devices and portable media devices.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an IMOD-based display, as described herein.

The components of the display device 40 are schematically illustrated in FIG. 10A. The display device 40 includes a housing 41 and can include additional components at least partially enclosed therein. For example, the display device 40 includes a network interface 27 that includes an antenna 43 which can be coupled to a transceiver 47. The network interface 27 may be a source for image data that could be displayed on the display device 40. Accordingly, the network interface 27 is one example of an image source module, but the processor 21 and the input device 48 also may serve as an image source module. The transceiver 47 is connected to a processor 21, which is connected to conditioning hardware 52. The conditioning hardware 52 may be configured to condition a signal (such as filter or otherwise manipulate a signal). The conditioning hardware 52 can be connected to a speaker 45 and a microphone 46. The processor 21 also can be connected to an input device 48 and a driver controller 29. The driver controller 29 can be coupled to a frame buffer 28, and to an array driver 22, which in turn can be coupled to a display array 30. One or more elements in the display device 40, including elements not specifically depicted in FIG. 10A, can be configured to function as a memory device and be configured to communicate with the processor 21. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g, n, and further implementations thereof. In some other implementations, the antenna 43 transmits and receives RF signals according to the Bluetooth® standard. In the case of a cellular telephone, the antenna 43 can be designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1×EV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G, 4G or 5G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that can be readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of display elements.

In some implementations, the driver controller 29, the array driver 22, and the display array 30 are appropriate for any of the types of displays described herein. For example, the driver controller 29 can be a conventional display controller or an active matrix display controller (such as an IMOD display element controller). Additionally, the array driver 22 can be a conventional driver or an active matrix display driver (such as an IMOD display element driver). Moreover, the display array 30 can be a conventional display array or a MEMS display array (such as a display including an array of IMOD display elements). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with the display array 30, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of, e.g., an IMOD display element as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, a person having ordinary skill in the art will readily recognize that such operations need not be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A microelectromechanical systems (MEMS) display device, comprising:
a substrate;
a movable reflective structure over the substrate, wherein the movable reflective structure includes an annealed thin film stack, the annealed thin film stack including:
a first layer including aluminum or aluminum alloy,
a second layer including aluminum or aluminum alloy and over the first layer,
a third layer between the first layer and the second layer and in contact with at least one of the first layer and the second layer, the third layer including a transition metal, the transition metal including at least one of: zirconium, scandium, ruthenium, titanium, tantalum, molybdenum, and chromium; and
one or more support structures over the substrate and connected to the movable reflective structure to support the movable reflective structure.

2. The device of claim 1, wherein one or both of the first layer and the second layer is doped with about 0.1 atomic % to about 10 atomic % of the transition metal.

3. The device of claim 1, wherein a stress of the movable reflective structure is less than about 200 MPa.

4. The device of claim 1, wherein the third layer has a thickness of less than about 5 nm, and the first layer and the second layer each have a thickness of equal to or greater than about 20 nm.

5. The device of claim 1, wherein a thickness of the third layer is about 10% or less than a total thickness of the thin film stack.

6. The device of claim 1, wherein a reflectance of the movable reflective structure is greater than about 80%.

7. The device of claim 1, wherein each of the first layer and the second layer is doped to include between about 1 atomic % and about 20 atomic % of one or both of oxygen and nitrogen.

8. The device of claim 1, wherein the third layer is in contact with both the first layer and the second layer.

9. The device of claim 1, wherein the first layer and the second layer are substantially identical in composition and thickness.

10. The device of claim 9, wherein the thin film stack further includes:
a fourth layer below the first layer, the fourth layer being substantially identical in composition and thickness with the third layer.

11. The device of claim 10, wherein the thin film stack further includes:
a fifth layer below the fourth layer, the fifth layer being substantially identical in composition and thickness with the first layer and the second layer.

12. The device of claim 1, further comprising:
a stationary electrode between the substrate and movable reflective structure, the stationary electrode and the movable reflective structure defining a gap therebetween, the movable reflective structure configured to move across the gap towards the stationary electrode by electrostatic force.

13. The device of claim 1, wherein the MEMS display device forms a display, the MEMS display device further comprising:
a processor that is configured to communicate with the display, the processor being configured to process image data; and
a memory device that is configured to communicate with the processor.

14. The device of claim 13, further comprising:
a driver circuit configured to send at least one signal to the display; and
a controller configured to send at least a portion of the image data to the driver circuit.

15. The device of claim 13, further comprising:
an image source module configured to send the image data to the processor, wherein the image source module comprises at least one of a receiver, transceiver, and transmitter.

16. The device of claim 13, further comprising:
an input device configured to receive input data and to communicate the input data to the processor.

17. A method of manufacturing a MEMS display device, the method comprising:
providing a substrate;
forming a support structure over the substrate;
forming a movable reflective structure over the substrate and connected to the support structure, wherein the movable reflective structure includes:
a first layer including aluminum or aluminum alloy;
a second layer including aluminum or aluminum alloy and over the first layer;
a third layer between the first layer and the second layer and in contact with at least one of the first layer and the second layer, the third layer including a transition metal, the transition metal including at least one of: zirconium, scandium, ruthenium, titanium, tantalum, molybdenum, and chromium; and
annealing the movable reflective structure.

18. The method of claim 17, wherein forming the movable reflective structure includes:
depositing the first layer over the substrate;
depositing the third layer on the first layer; and
depositing the second layer on the third layer.

19. The method of claim 18, wherein depositing the first layer includes doping the first layer with one or both of oxygen and nitrogen, and wherein depositing the second layer includes doping the second layer with one or both of oxygen and nitrogen.

20. The method of claim 18, further comprising:
depositing a fourth layer between the substrate and the first layer, wherein the fourth layer is substantially identical in thickness and composition with the third layer.

21. The method of claim 20, further comprising:
depositing a fifth layer between the substrate and the fourth layer, wherein the fifth layer is substantially identical in thickness and composition with the first layer and the second layer.

22. The method of claim 17, wherein annealing the movable reflective structure includes doping the first layer and the second layer with the transition metal.
